(19) United States
(12) Patent Application Publication
(10) Pub. No.: US 2005/0242708 A1
(43) Pub. Date: Nov. 3, 2005

(54) LED device with a vertical leadframe that is configured for surface mounting

(76) Inventors: Chong Chee Keong, Perai (MY); Seah Keh Chin, Penang (MY); Kuan Yew Cheong, Penang (MY); Foong Kar Phooi, Bayan Lepas (MY); Tee Tah Wee, Penang (MY); Lim Kok Peng, Bayan Lepas (MY); Cheng Kai Chong, Penang (MY)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/836,470

(22) Filed: Apr. 30, 2004

(51) Int. Cl. H01L 23/495

(52) U.S. Cl. 313/498

(57) ABSTRACT

A Light Emitting Diode (LED) device with a vertical leadframe includes a lamp structure and a leadframe vertically aligned within the lamp structure. The leadframe includes a portion outside of the lamp structure that is configured for surface mounting. Since the leadframe is vertically aligned, a reflector cup connected to the leadframe can be relatively deep.

### BACKGROUND OF THE INVENTION

Light Emitting Diodes (LEDs) are widely used in applications such as Liquid Crystal Display (LCD) back lighting, commercial-freezer lighting, white light illumination, etc. LEDs are typically available in through-hole and Surface Mount Technology (SMT) packages. Through-hole packages are ideal for wave solder board applications. Such through-hole LEDs are typically manufactured with a leadframe having two leads. SMT packages are best used with reflow assembly. SMT devices are also useful when package size constraints are an issue. SMT devices are typically manufactured with a leadframe, or a Printed Circuit Board (PCB) or ceramics substrate.

FIG. 1 depicts a prior art SMT LED device 100 manufactured using a leadframe. The device 100 includes a base 102, a lens 104, a reflector cup 110, a wire 112, and a die 114. The device 100 also includes a leadframe with a first lead 106 and a second lead 108. The leadframe is typically a metallic frame that functions as an electrical conduit for the die. The base 102 holds the device 100 together. The die 114 is typically a small square of semi-conducting material that is the “active” light emitting component of the device 100. The wire 112 connects the die 114 to the second lead 108, completing a circuit. The reflector cup 110 serves to reflect light from the die 114 through the lens 104.

SMT LED devices that use leadframes have the leadframe positioned in a horizontal plane within the base. A disadvantage of positioning the leadframe in the horizontal plane within the base is that the depth of the reflector cup is limited. Limiting the reflector cup depth in turn limits the efficiency of the LED.

### SUMMARY OF THE INVENTION

A Light Emitting Diode (LED) device with a vertical leadframe includes a lamp structure and a leadframe vertically aligned within the lamp structure. The leadframe includes a portion outside of the lamp structure that is configured for surface mounting. For example, the portion of the leadframe that is outside of the lamp structure can be configured as L-wing, J-wing, or G-wing leads. Since the leadframe is vertically aligned within the lamp structure, a reflector cup connected to the leadframe can be relatively deep in comparison to traditional surface mounted LEDs.

### BRIEF DESCRIPTION OF THE DRAWINGS

FIG. 1 depicts a prior art SMT LED device.

FIGS. 2A and 2B depict side and front views of an SMT LED device according to an embodiment of the invention.

FIG. 3 depicts a front view of an alternative SMT LED device according to an embodiment of the invention.

FIGS. 4A to 4D depict a side view and perspective views of alternative L-form SMT LED devices according to embodiments of the invention.

FIGS. 5A to 5D depict a side view and perspective views of alternative J-form SMT LED devices according to embodiments of the invention.

FIGS. 6A to 6D depict a side view and perspective views of alternative G-form SMT LED devices according to embodiments of the invention.

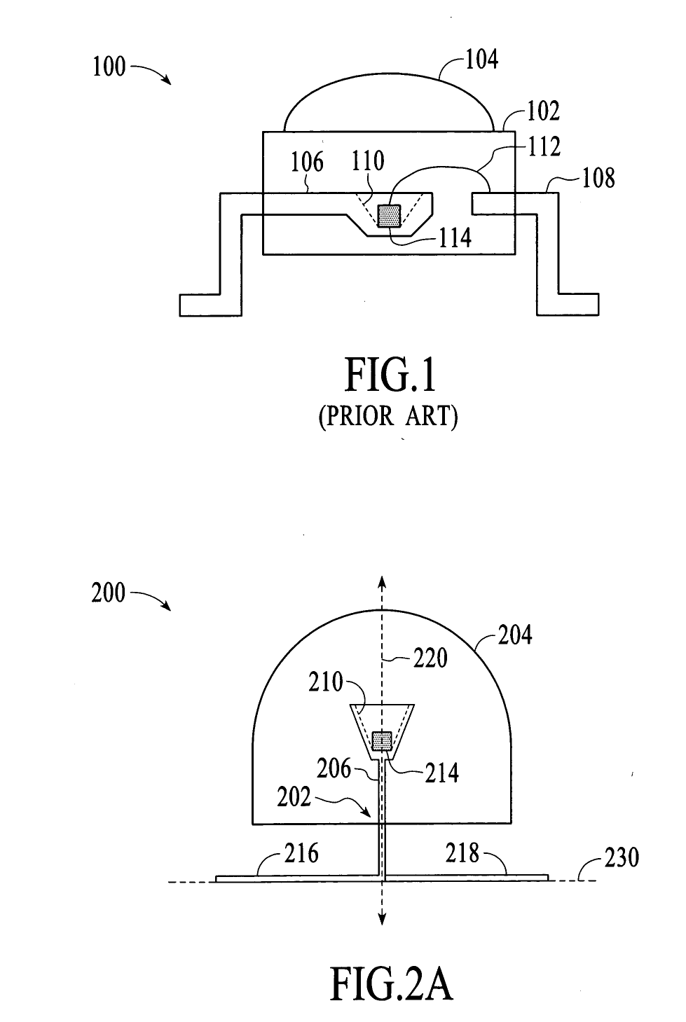

Throughout the description, similar reference numbers may be used to identify similar elements.

### DETAILED DESCRIPTION OF THE INVENTION

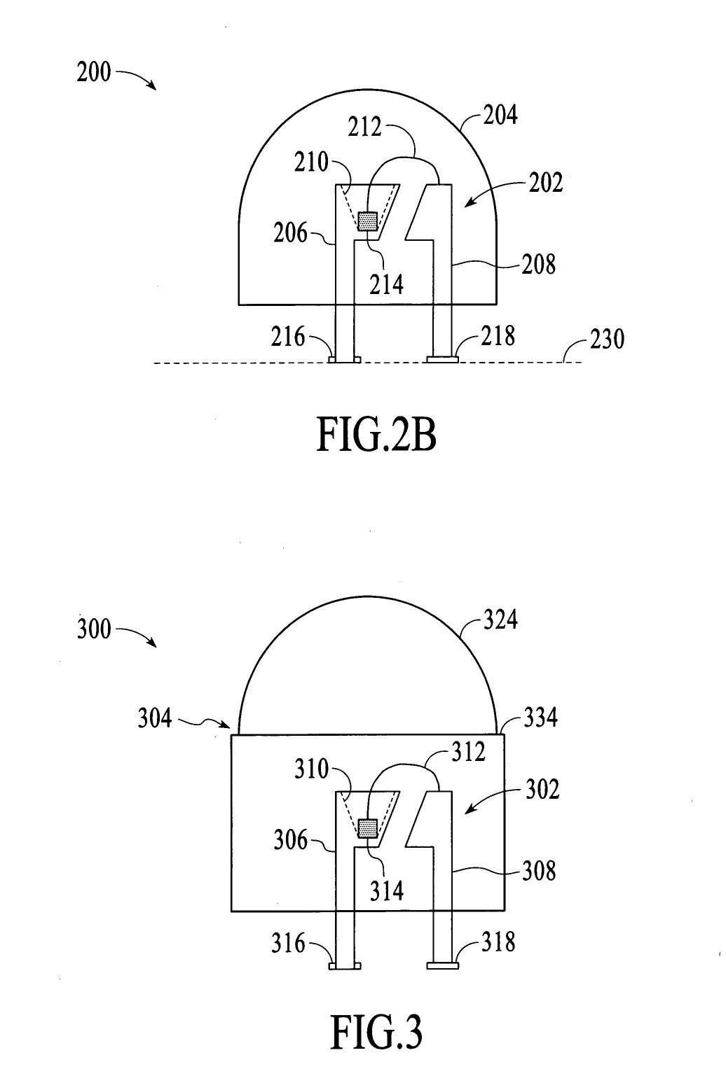

FIG. 2A depicts a side view of a Light Emitting Diode (LED) device 200. The device 200 includes a leadframe 202, a lamp structure 204, a reflector cup 210, and an LED die 214. The device 200 is configured for mounting on a surface 230.

In the example of FIG. 2A, the leadframe 202 includes two leads, a lead 206 and a lead 208 (depicted in FIG. 2B). The leadframe 202 is in a vertical plane 220 within the lamp structure 204 with respect to the surface 230. Note that since FIG. 2A depicts a side view of the device 200, the vertical plane 220 appears as a line in FIG. 2A. The lead 206 includes a portion 216 that is outside of the lamp structure 204. A portion 218 of the lead 208 (FIG. 2B) is also outside of the lamp structure 204. The portions 216 and 218 of the leads that are outside of the lamp structure 204 are configured for surface mounting. The leadframe 202 may be considered to be vertically aligned because, when surface mounted, the leads 206, 208 extend in a vertical direction relative to the surface 230. In an alternative, the leadframe 202 may be vertically aligned with respect to the lamp structure 204, but oblique with respect to the surface 230. Alternatively, the leadframe is vertically aligned when the leadframe extends through the lamp structure 204 from the bottom of the lamp structure 204 toward the top along the vertical plane 220.

The reflector cup 210 is connected to, and in the vertical plane 220 with the lead 206. The reflector cup 210 could be formed from a portion of the leadframe. The LED die is located within the reflector cup 210. The reflector cup 210 may be considered to be vertically aligned because it is connected to the lead 206, which extends vertically with respect to the surface 230. Since the reflector cup 210 is vertically aligned with the lead 206, the reflector cup 210 can be relatively deep, which can improve light distribution. Moreover, since the reflector cup 210 is in the vertical plane 220 with the lead 206, the reflector cup 210 can be conveniently located inside the lamp structure 204.

In the example of FIG. 2A, the reflector cup 210 is encased in epoxy, which serves as a lens. Accordingly, in the example of FIG. 2A, the lamp structure 204 may be referred to as a lens. The leadframe 202 is in a vertical plane within the lens. The lens may be any type of lens that is known in the art of LED lens manufacture, including but not limited to casting type lenses, transfer-molding type lenses, and injection-molded lenses.

FIG. 2B depicts a front view of the device 200. The lead 208, which was behind the lead 206 in FIG. 2A, is visible in FIG. 2B. Also, the wire 212 connecting the LED die 214 to the lead 208, which was omitted from FIG. 2A, is visible in FIG. 2B. The perspective view of FIG. 2B, in conjunction with the perspective view of FIG. 2A, depicts an exemplary vertical leadframe 202. The portion of the leadframe 202 that is outside of the lamp structure 204 is configured in what is referred to as an L-wing form because the leadframe 202 has the shape of an “L”. For stability, the lower legs of the L-wing typically point away from the center of the lens and are perpendicular to the vertical plane 220. However, this is not critical.

FIG. 3 depicts a front view of an alternative LED device 300. While similar to the device 200 (FIGS. 2A and 2B), the lamp structure 304 includes a lens 324 and a base 334. A lamp structure including a lens connected to a base is known in the art of LED device manufacturing. As depicted in FIG. 3, the lens 324 is connected to the top surface of the base 334. In the example of FIG. 3, the lens 324 is a dome on top of the base 334. The leads 306, 308 are connected to the base 334 such that bottom surface of the base intersects the leads 306, 308. Thus, as is the case for the device 200 (FIGS. 2A and 2B), the leads 206, 208 are vertically aligned with respect to the lamp structure 304. In contrast, prior art Surface Mount Technology (SMT) LED devices have horizontally aligned leadframes and leads. In an alternative, the leads 206, 208 may be vertically aligned with respect to the lens 324, but oblique with respect to the base 334.

It should be noted that the reflector cup 310 is depicted within the base 334. However, in another embodiment, the reflector cup 310 could be located entirely within the lens 324. Indeed, one of the notable advantages of the vertical leadframe is that the leadframe can be positioned in a vertical plane within the lens 324 as opposed to being positioned in the base 334.

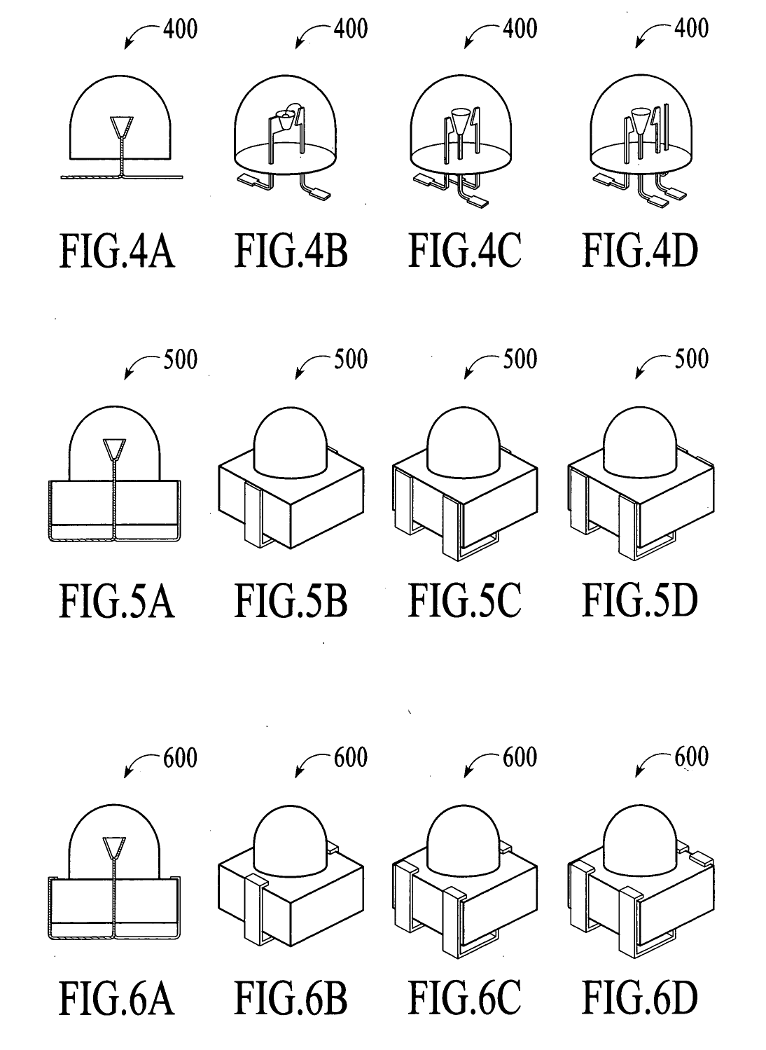

FIGS. 4A, 4B, 4C, and 4D depict L-wing configurations for an SMT LED device 400 that is similar to the device 200 (FIGS. 2A and 2B). With each of these devices, the leadframe and reflector cup are vertically aligned within the lamp structure while the leads are configured for surface mounting. FIG. 4A is a side view of a device 400 with an L-wing configuration. As depicted in FIG. 4A, the portion of the leadframe that is outside of the lamp structure has a roughly “L” shape, which is why the configuration is referred to as an L-wing configuration. FIG. 4B depicts a front view of the device 400 having a leadframe with 2 leads. FIG. 4C depicts a front view of an alternate device 400 having a leadframe with 3 leads. FIG. 4D depicts a front view of an alternate device 400 having a leadframe with 4 leads. For the purposes of example, the leadframe is in a vertical plane within the lamp structure in each of the FIGS. 4A to 4D.

FIGS. 5A, 5B, 5C, and 5D depict J-wing configurations for an SMT LED device 500. FIG. 5A is a side view of a device 500. With each of these devices, the leadframe and reflector cup are vertically aligned within the lamp structure while the leads are configured for surface mounting. As depicted in FIG. 5A, the leadframe has a roughly “J” shape, which is why the configuration is referred to as a J-wing configuration. FIG. 5B depicts a front view of the device 500 having a leadframe with 2 leads. FIG. 5C depicts a front view of an alternate device 500 having a leadframe with 3 leads. FIG. 5D depicts a front view of an alternate device 500 having a leadframe with 4 leads. For the purposes of example, the leadframe is in a vertical plane within the lamp structure in each of the FIGS. 5A to 5D.

FIGS. 6A, 6B, 6C, and 6D depict G-wing configurations for an SMT LED device 600. FIG. 6A is a side view of a device 600. With each of these devices, the leadframe and reflector cup are vertically aligned within the lamp structure while the leads are configured for surface mounting. As depicted in FIG. 6A, the leadframe has a roughly “G” shape, which is why the configuration is referred to as a G-wing configuration. FIG. 6B depicts a front view of the device 600 having a leadframe with 2 leads. FIG. 6C depicts a front view of an alternate device 600 having a leadframe with 3 leads. FIG. 6D depicts a front view of an alternate device 600 having a leadframe with 4 leads. For the purposes of example, the leadframe is in a vertical plane within the lamp structure in each of the FIGS. 6A to 6D.

Horizontal position, as used herein, describes a position that is horizontal relative to the surface on which a SMT device is mounted. Similarly, vertical position describes a position that is vertical relative to the surface on which the SMT device is mounted. Vertical alignment, as used herein, means approximately vertical alignment, not exact perpendicularity.

Although specific embodiments of the invention have been described and illustrated, the invention is not to be limited to the specific forms or arrangements of parts as described and illustrated herein. The invention is limited only by the claims.

1. A Light Emitting Diode (LED) device, comprising:
a lamp structure; and
a leadframe vertically aligned within said lamp structure, wherein
said leadframe includes a portion outside of said lamp structure, and wherein
said portion that is outside of said lamp structure is configured for surface mounting.

2. The device of claim 1 further comprising a reflector cup connected to and vertically aligned with said leadframe.

3. The device of claim 1 wherein said leadframe is in a vertical plane within said lamp structure.

4. The device of claim 1 wherein said leadframe includes multiple leads.

5. The device of claim 4 further comprising:
a reflector cup connected to, and in a vertical plane with, one of said multiple leads, and
an LED die within said reflector cup.

6. The device of claim 1 wherein said portion of the leadframe that is outside of said lamp structure has a configuration selected from the group consisting of L-wing configuration, J-wing configuration, and G-wing configuration.

7. The device of claim 1 wherein said lamp structure includes a lens selected from the group consisting of casting-type epoxy lens, transfer-molding type epoxy lens, and injection-molded lens.

8. A Light Emitting Diode (LED) device, comprising:
a lens;
a leadframe that includes a portion outside of said lens, wherein said portion that is outside of said lens is configured for surface mounting; and
a reflector cup, connected to said leadframe, vertically aligned with said leadframe.

9. The device of claim 8 wherein said leadframe is in a vertical plane within said lens.

10. The device of claim 8 wherein said lens is selected from the group consisting of casting-type epoxy lens, transfer-molding type epoxy lens, and injection-molded lens.

11. The device of claim 8 wherein said leadframe includes multiple leads.

12. The device of claim 11 further comprising a die within said reflector cup, wherein said reflector cup is connected to, and vertically aligned with, one of said multiple leads.

13. The device of claim 8 wherein said portion that is outside of said lens has a configuration selected from the group consisting of L-wing configuration, J-wing configuration, and G-wing configuration.

14. A Light Emitting Diode (LED) device, comprising:
a lamp structure having a bottom surface; and
a leadframe, connected to said lamp structure, that includes a portion outside of said lamp structure, wherein
said bottom surface of said lamp structure intersects said leadframe, and wherein
said portion of the leadframe that is outside of said lamp structure is configured for surface mounting.

15. The device of claim 14 wherein said leadframe is in a vertical plane within said lamp structure.

16. The device of claim 14 wherein said lamp structure includes a lens selected from the group consisting of casting-type epoxy lens, transfer-molding type epoxy lens, and injection-molded lens.

17. The device of claim 14 wherein said lamp structure includes a base selected from the group consisting of casting-type epoxy lens, transfer-molding type epoxy lens, and injection-molded lens.

18. The device of claim 14 wherein said leadframe includes multiple leads.

19. The device of claim 18 further comprising:
a reflector cup connected to, and vertically aligned with, one of said multiple leads; and
an LED die within said reflector cup.

20. The device of claim 14 wherein said portion that is outside of said base has a configuration selected from the group consisting of L-wing configuration, J-wing configuration, and G-wing configuration.
